(19) United States
(12) Patent Application Publication
(10) Pub. No.: US 2014/0284683 A1
(43) Pub. Date: Sep. 25, 2014

(54) SEMICONDUCTOR DEVICE AND MANUFACTURING METHOD OF SEMICONDUCTOR DEVICE

(71) Applicant: Kabushiki Kaisha Toshiba, Minato-ku (JP)

(72) Inventor: Sachiyo ITO, Yokohama-shi (JP)

(73) Assignee: Kabushiki Kaisha Toshiba, Minato-ku (JP)

(21) Appl. No.: 14/027,560

(22) Filed: Sep. 16, 2013

(30) Foreign Application Priority Data
Mar. 19, 2013 (JP) 2013-056962

(51) Int. Cl. H01L 29/423; H01L 29/66; H01L 29/788

(52) U.S. Cl. CPC H01L 29/42324; H01L 29/788; H01L 29/66825
USPC 257/316; 438/593

(57) ABSTRACT

According to one embodiment, a semiconductor device includes a memory cell, a dummy gate electrode and an interlayer insulation film. The memory cell includes a plurality of word lines as an arrangement on a semiconductor substrate and apart from each other, and a selection transistor being apart from an end of the arrangement. The dummy gate electrode has a structure larger than a word line in the arrangement direction, and is arranged between the end of the arrangement and the selection transistor. The interlayer insulation film is existed above a region including the word line, the dummy gate electrode and the selection transistor, and between the neighboring word lines, the dummy gate electrode and the selection transistor, and has a cavity between the neighboring word lines.

### CROSS-REFERENCE TO RELATED APPLICATIONS

This application is based upon and claims the benefit of priority from Japanese Patent Application No. 2013-056962, filed Mar. 19, 2013, the entire contents of which are incorporated herein by reference.

### FIELD

Embodiments described herein relate generally to a semiconductor device and a manufacturing method of a semiconductor device such as an NAND flash memory.

### BACKGROUND

As a semiconductor device, there has been a nonvolatile semiconductor memory device in which an oxide film or a nitride film fills spaces between a plurality of word lines apart from each other. In this kind of semiconductor device, miniaturization of elements reduces a distance between the word lines, and a parasitic capacitance occurring between floating gate electrodes of neighboring word lines or between a floating gate and a diffusion layer lowers a writing speed. In view of this, such a manner has been proposed that deposits an oxide film of a low embedding property on and between the word lines, and thereby forms an air gap (cavity) between the neighboring floating gate electrodes to suppress a parasitic capacitance.

### BRIEF DESCRIPTION OF THE DRAWINGS

FIG. 1 illustrates a part of an NAND flash memory according to a first embodiment;

FIG. 2A illustrates a manufacturing method of the NAND flash memory;

FIG. 2B illustrates a manufacturing method of the NAND flash memory;

FIG. 2C illustrates a manufacturing method of the NAND flash memory;

FIG. 2D illustrates a manufacturing method of the NAND flash memory;

FIG. 2E illustrates a manufacturing method of the NAND flash memory;

FIG. 3 is a graph showing a volume shrinkage rate of an interlayer insulation film of the NAND flash memory;

FIG. 4A illustrates deformations due to the volume shrinkage of the NAND flash memory;

FIG. 4B illustrates deformations due to the volume shrinkage of a comparison example;

FIG. 5 is a graph showing a relationship between the number of dummy gate electrodes and a deformation amount of the word line;

FIG. 6 is a graph showing a relationship between a width of a dummy gate electrode and deformation amounts of the word line and the dummy gate electrode; and

FIG. 7 illustrates a part of an NAND flash memory according to a second embodiment.

### DETAILED DESCRIPTION

In general, according to one embodiment, a semiconductor device includes a memory cell, a dummy gate electrode and an interlayer insulation film. The memory cell includes a plurality of word lines as an arrangement on a semiconductor substrate and apart from each other, and a selection transistor being apart from an end of the arrangement. The dummy gate electrode has a structure larger than a word line in the arrangement direction, and is arranged between the end of the arrangement and the selection transistor. The interlayer insulation film is existed above a region including the word line, the dummy gate electrode and the selection transistor, and between the neighboring word lines, the dummy gate electrode and the selection transistor, and has a cavity between the neighboring word lines.

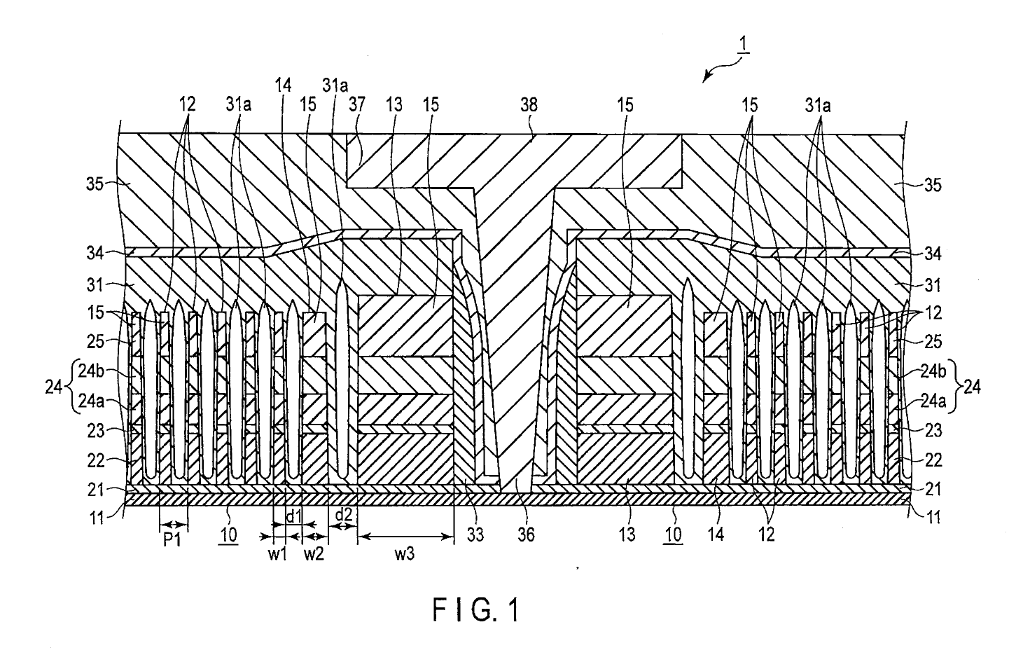

The semiconductor device and a method of manufacturing the semiconductor device of the first embodiment will be described below with reference to FIGS. 1 to 6. In each figure, structures are appropriately enlarged, reduced or eliminated.

FIG. 1 is a cross section showing a part of an NAND flash memory 1 which is an example of the semiconductor device, and shows a memory cell array region. The NAND flash memory 1 includes a memory cell array region and a peripheral circuit region provided with peripheral circuits performing writing, reading and erasing on the memory cell array region. The memory cell array region has a plurality of memory cells 10.

FIG. 1 shows NAND strings formed of word lines 12 standing in line as well as dummy gate electrodes 14 and selection transistors 13 arranged at the ends of the arrangements of the word lines 12, and also shows a contact hole 36 arranged between the neighboring selection transistors. The plurality of memory cells 10 are arranged.

As shown in FIG. 1, the memory cell 10 of the NAND flash memory 1 is provided on a semiconductor substrate 11 with the plurality of word lines 12 arranged with a predetermined space therebetween, and the selection transistors 13 arranged at ends of the arrangement.

At the opposite ends of the memory cell 10, there are arranged dummy gate electrodes 14, respectively, each of which has a larger width and a larger mechanical strength than the word line 12 and is located between the selection transistor 13 and the word line 12 located at the end among the plurality of word lines 12.

Each of the word lines 12, the selection transistor 13 and the dummy gate electrode 14 has a multilayered gate structure 15 formed at the semiconductor substrate 11. The multilayered gate structure 15 is formed by successively layering a tunnel oxide film 21 (first insulation film) made of a silicon oxide film, a floating gate electrode 22 made of a polycrystalline silicon film, an interpoly insulation film 23 (second insulation film), a control gate electrode 24 and a mask layer 25 used as a mask for forming the word line 12 by dry etching on the semiconductor 11.

The control gate electrode 24 is made of a multilayered structure of polycrystalline silicon 24a and an electrically conductive material 24b. Metal such as W, Ni Ti, Co, Pt, Pd, Ta or Mo, a nitride film thereof, a silicide film thereof or a multilayered structure thereof may be used as the electrically conductive material.

A nitride film or an oxide film of Si, Al, Ti or the like, or a multilayered film thereof may be used as the mask layer 25.

An interlayer insulation film 31 made of a silicon oxide film is deposited above the memory cells 10 including the multilayered gate structures 15 of the plurality of word lines 12, the selection transistors 13 and the dummy gate electrodes 14 and between the neighboring multilayered gate structures 15.

Since the silicon oxide film is formed by, e.g., a plasma CVD method that is a deposition method of a low embedding property, air gaps 31a (cavities) are formed between the plurality of neighboring word lines 12, the selection transistor 13 and the dummy gate electrode 14. The air gap 31a ensures insulation between the floating gate electrodes 22 of the neighboring word lines 12. The interlayer insulation film 31 may not completely surround the air gaps 31a. Also, the air gap 31a may not be formed between the selection transistor 13 and the dummy gate electrode 14.

A spacer oxide film 33 made of a silicon oxide film is formed on the sidewall of the selection transistor 13. A liner layer 34 made of a silicon nitride film is deposited over the interlayer insulation film 31 and the spacer oxide film 33.

The contact hole 36 is formed between the neighboring selection transistors 13. A second interlayer insulation film 35 made of a silicon oxide film is formed on the liner layer 34, and an interconnection groove 37 connected to the contact hole 36 is arranged in the interlayer insulation film 35. An electrically conductive material 38 is deposited in the contact hole 36 and the interconnection groove 37. Metal such as W, Ni, Ti, Co, Pt, Pd, Ta or Mo, a nitride film thereof, a silicide film or a multilayered structure thereof may be used as the electrically conductive material 38.

As shown in FIG. 1, when the word line 12 has a width size of W1 in its side-by-side direction, a width size W2 of the dummy gate electrode 14 is larger than the width size W1 of each word line 12, and is smaller than a width size W3 of the selection transistor 13. The width size W2 of the dummy gate electrode 14 is equal to or larger than a pitch P1 of arrangement of the word lines 12, and is equal to or smaller than ½ of the width size W3 of the selection transistor 13. A distance d2 between the dummy gate electrode 14 and the selection transistor 13 is equal to or smaller than the pitch P1 of arrangement of the word lines 12.

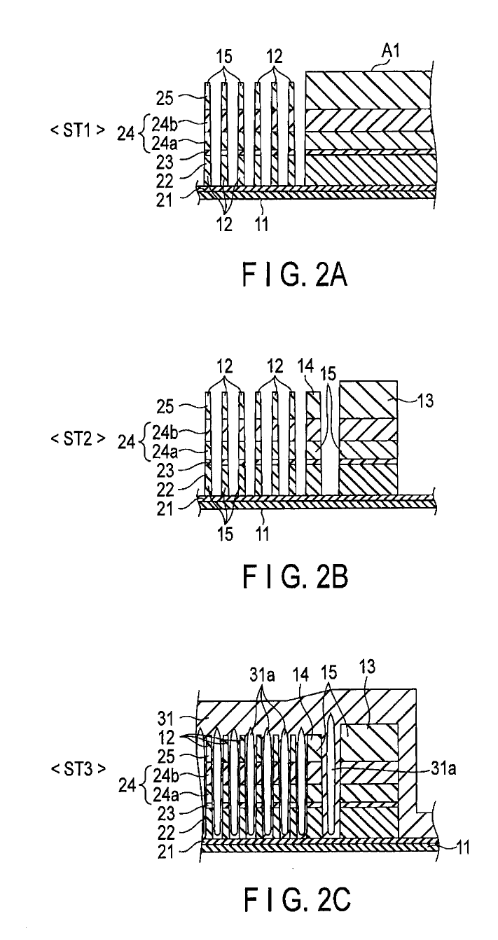

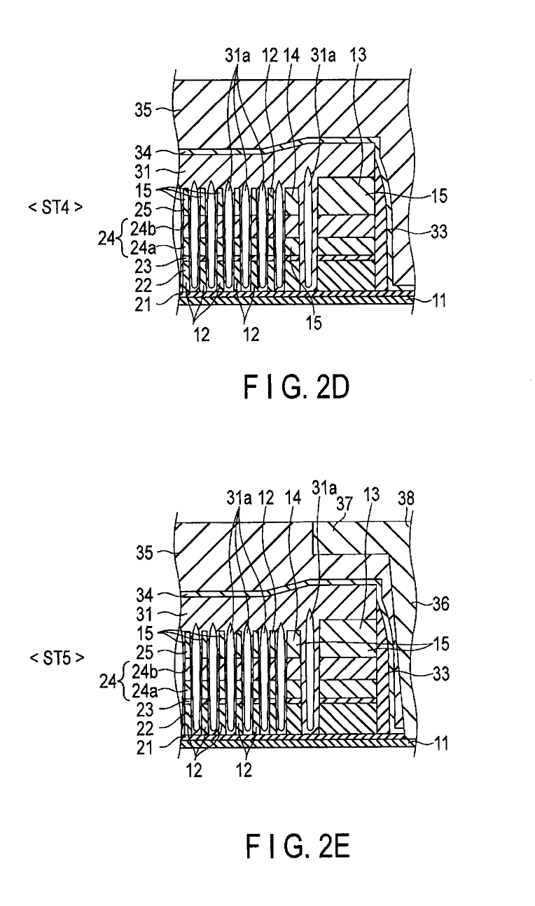

Referring to FIG. 2A to 2E, a method of manufacturing a semiconductor device 1 will be described below. FIG. 2A to 2E shows only a left half of FIG. 1. First, the word lines 12 are formed as shown in <ST1> in FIG. 2A. In the processing steps of the word lines 12, general manufacturing steps of the NAND flash memory 1 are first performed to form the tunnel oxide film 21 made of the silicon oxide film and the floating gate electrode 22 made of the polycrystalline silicon film on the semiconductor substrate 11. Grooves are formed in a direction perpendicular to a sheet of FIG. 2A by removing portions of the floating gate electrode 22, the tunnel oxide film 21 and the semiconductor substrate 11 that are apart from each other by a predetermined distance. These grooves are filled by a predetermined height with the silicon oxide film to form an element isolation region (not shown). The interpoly insulation film 23 is formed over the floating gate electrode 22 and the element isolation region, and the control gate electrode 24 and the mask layer 25 are layered on the interpoly insulation film 23. An RIE (Reactive Ion Etching) processing is performed to leave a region A1 in which the word lines 12 standing in line and having the predetermined width W1 and apart at the predetermined pitch P1 as well as the dummy gate electrode 14 and the selection transistor 13 neighboring to the end of the word lines 12 are formed. The above processing forms and processes the plurality of word lines 12 standing in line and apart by a predetermined distance.

Then, as shown in <ST2> of FIG. 2B, the RIE (Reactive Ion Etching> processing is performed to remove a part of the region A1 except for the dummy gate electrode 14 of the predetermined width W2 neighboring to the word line 12 with the predetermined distance d1 apart therefrom as well as the selection transistor 13 of a predetermined width W3 neighboring to the dummy gate electrode 14 with a predetermined distance d2 apart therefrom. Thereby, the dummy gate electrode 14 and the selection transistor 13 are processed. Thus, after processing the word lines 12, the dummy gate electrode 14 is formed simultaneously with the processing of the selection transistor 13.

Instead of the above procedures <ST1> and <ST2>, the dummy gate electrode 14 may be formed simultaneously with the processing of the word lines 12 by removing a portion between the word line 12 at the end and the dummy gate electrode 14 as well as a portion between the dummy gate electrode 14 and the selection transistor 13. The selection transistor 13 is processed after the dummy gate electrode 14 was formed simultaneously with the processing of the word lines 12. Further, the word lines 12, the dummy gate electrode 14 and the selection transistor 13 may be formed simultaneously.

Then, as shown in <ST3> in FIG. 2C, the interlayer insulation film 31 is formed by depositing a silicon oxide film on the region including the word lines 12, the dummy gate electrode 14 and the selection transistor 13, e.g., by the plasma CVD method. The interlayer insulation film 31 covers the upper portions of the word lines 12, the dummy gate electrode 14 and the selection transistor 13, and fills the spaces between the multilayered gate structures 15 of the neighboring word lines 12, the dummy gate electrode 14 and the selection transistors 13. Since the plasma CVD method is the deposition method exhibiting a poor embedding property, it does not fill a part of the regions. Therefore, the unfilled portions form the air gaps 31a between the neighboring multilayered gate structures 15.

Subsequently, as shown in <ST4> in FIG. 2D, a part of the interlayer insulation film 31 between the selection transistors 13 of the neighboring memory cells 10 is removed by the RIE processing to form the spacer oxide film 33. Further, the liner layer 34 and the second interlayer insulation film 35 are successively deposited, e.g., by the plasma CVD method.

As shown in <ST5> in FIG. 2E, the contact hole 36 and the interconnection groove 37 are formed in the second interlayer insulation film 35 by the RIE processing. The electrically conductive material 38 is deposited in the contact hole 36 and the interconnection groove 37, and the electrically conductive material 38 on the second interlayer insulation film 35 except for the interconnection groove 37 is removed by CMP (Chemical Mechanical Polish) to form the structure shown in FIG. 1.

The above steps of manufacturing the semiconductor device include a plurality of thermal processing steps. For example, annealing processing is performed for the purposes of activating and diffusing the implanted impurities after depositing the liner layer 34 and for repairing damages caused in the wafer crystal structure by the implantation. This processing raises the temperature of the interlayer insulation film 31 to, e.g., about 950° C.

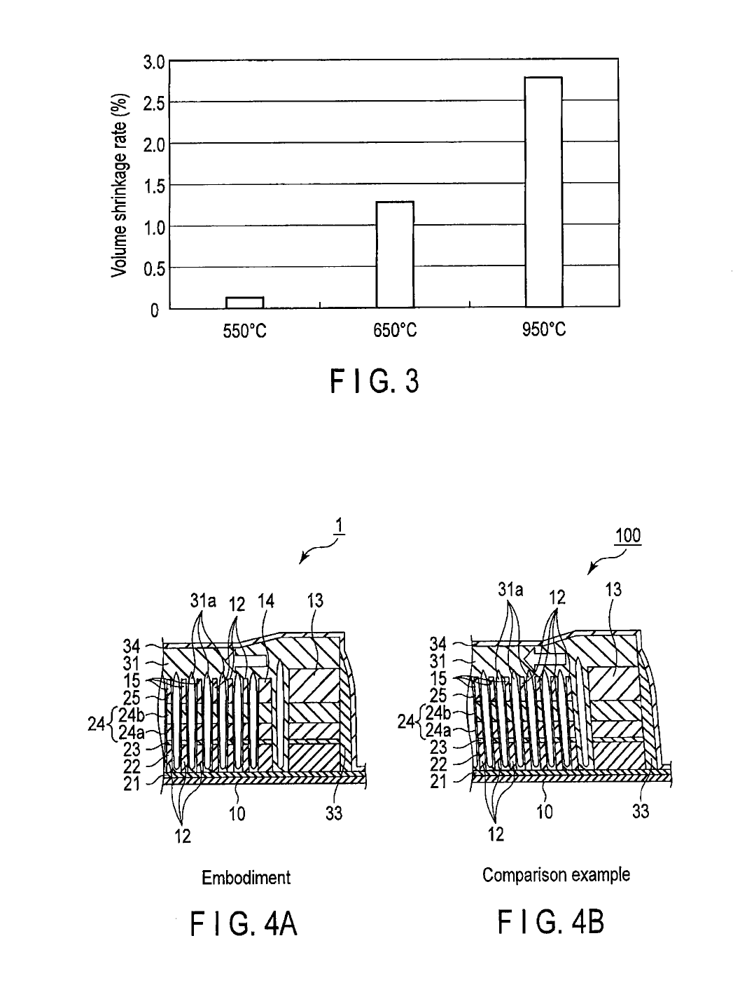

FIG. 3 shows a relationship between a temperature and a volume shrinkage ratio of the silicon oxide film forming the interlayer insulation film 31. As shown in FIG. 3, the annealing processing raises the temperature to about 950° C. so that volume shrinkage of about 3% occurs in the interlayer insulation film 31 due to the heat.

FIG. 4A illustrates deformation that occurs in the NAND flash memory 1 according to the embodiment and particularly the deformation in the annealing step after the deposition of the liner layer 34. FIG. 4B illustrates deformation that occurs in an NAND flash memory 100 of a comparison example not provided with the dummy gate electrode 14 and particularly the deformation in the annealing step after the deposition of the liner layer 34. As shown in FIG. 4A and 4B, when the volume shrinkage occurs in the interlayer insulation film 31, a force directed toward the center of the memory cell 10 occurs as indicated by an arrow in the end of the arrangement of the word lines 12. The fine word line 12 has a small width size, and the structure provided with the air gap 31a between the word lines 12 has a low mechanical strength so that the force due to this volume shrinkage is liable to deform the structure. In the NAND flash memory 100 not provided with the dummy gate electrode 14, the word line 12 at the end neighboring to the selection gate 13 has a larger asymmetry in structure than the word line 12 in or near the center of the NAND strings, and therefore stress concentration is liable to occur so that the volume shrinkage of the interlayer insulation film 31 causes a large amount of deformation. Therefore, the influence of the volume shrinkage caused by the thermal processing deforms and bends the word lines 12 toward a center of the memory cell 10. In the NAND flash memory 1 according to the embodiment, the dummy gate electrode 14 larger in width than the word line 12 and smaller in width than the selection gate 13 is formed between the word line 12 and the selection gate 13. This lowers the asymmetry of the structure, relieves the stress concentration and thereby suppresses the deformation of the word lines 12.

FIG. 5 shows the amounts of deformation in the embodiment provided with the dummy gate electrode 14, the comparison example, i.e., the NAND flash memory 100 not provided with the dummy gate electrode 14 and another embodiment which is a NAND flash memory 2 having two dummy gate electrodes 14 arranged in line. As shown in FIG. 5, the NAND flash memories 1 and 2 provided with the dummy gate electrodes 14 can reduce amounts of deformation of the word lines 12 as compared with the NAND flash memory 100 not provided with the dummy gate electrode 14.

The NAND flash memory 1 according to the embodiment and the NAND flash memory 100 of the structure not provided with the dummy gate electrode 14 were determined by observing, with a scanning electron microscope, the sectional forms after the step of removing the electrically conductive material 38 on the second interlayer insulation film 35 except for the interconnection groove 37 by the CMP. In the NAND flash memory 100 not provided with the dummy gate electrode 14, it was observed that a crack extended from a tip end of the air gap 31a toward the upper layer due to an external force onto the deformed air gap 31a by the CMP. In the NAND flash memory 1 according to the embodiment, the generation of the crack starting from the end of the air gap 31a was not observed.

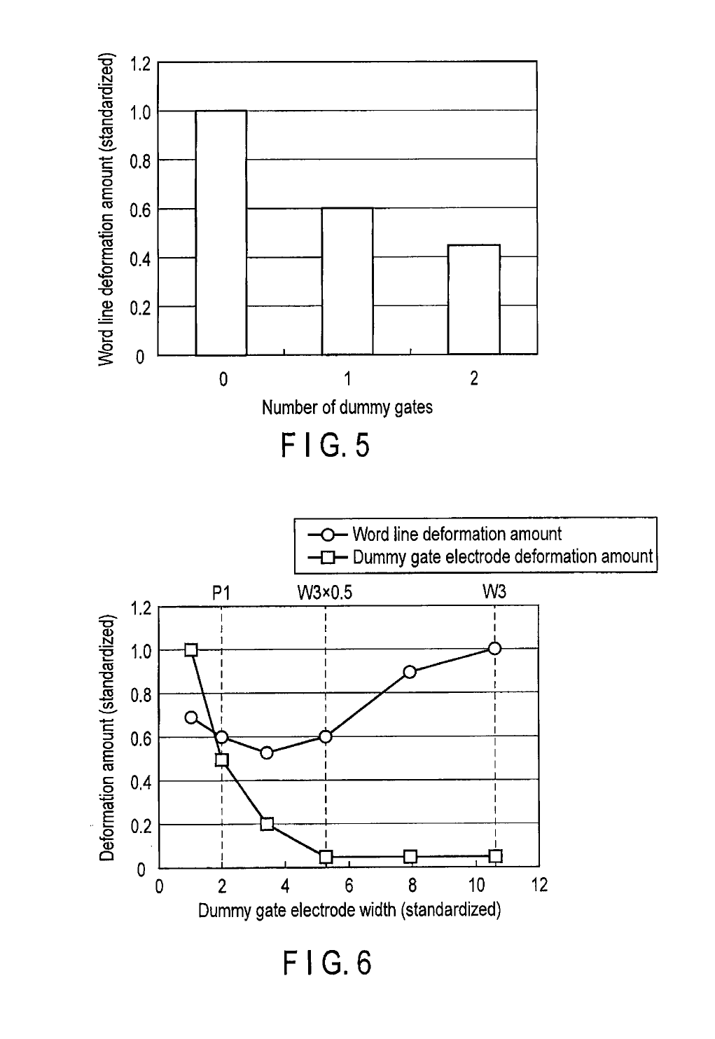

FIG. 6 illustrates a dependency of the deformation amounts of the word line 12 and the dummy gate electrode 14 in the NAND flash memory 1 provided with the dummy gate electrode 14 on the width of the dummy gate electrode 14. When the dummy gate electrode 14 has a small width, the asymmetry of the structures of the dummy gate electrode 14 and the selection gate 13 is large so that the dummy gate electrode 14 itself deforms to a large extent. In this case, the deformation of the dummy gate electrode 14 reduces the distance to the word line 12, and this may cause leakage between the word lines and/or cracking due to the deformation of the air gap. Conversely, when the dummy gate electrode 14 has a large width close to the width of the selection gate 13, the asymmetry of the structures of the word line 12 and the dummy gate electrode 14 increases, and the effect of suppressing the asymmetry of the structures by the dummy gate electrode 14 lowers so that the amount of deformation of the word lines 12 increases. As illustrated, by way of example, in FIG. 6, it is desired that the width of the dummy gate electrode 14 is equal to or larger than the pitch P1 of the arrangement of the word lines 12, and is equal to or smaller than ½ of the width size W3 of the selection transistor 13.

According to the semiconductor device 1 and the manufacturing method of the semiconductor device 1 of the embodiment, the provision of the dummy gate electrode 14 of a large width at the end of the memory cell region improves the mechanical strength at the end of the memory cell 10, and can suppress the deformation due to the volume shrinkage in the thermal processing after formation of the air gaps 31a. Thus, in the embodiment, the wide dummy gate electrode 14 of the high mechanical strength can receive, at the end of the memory cell 10, the force directed to the center of the memory cell 10. Therefore, the embodiment can suppress the deformation of the word lines 12 due to the volume shrinkage.

Since the dummy gate electrode 14 has the multilayered structure formed similarly to the word line 12 and the selection transistor 13, the dummy gate electrode 14 can be formed simultaneously during the processing of the word lines 12 and the selection transistor 13, resulting in the simple manufacturing process.

In the above embodiment, one dummy gate electrode 14 is arranged between the selection transistor 13 and the word line 12 in the opposite ends of the memory cell 10. However, this example is not restrictive, and the plurality of dummy gate electrodes 14 may be formed at each of the opposite ends.

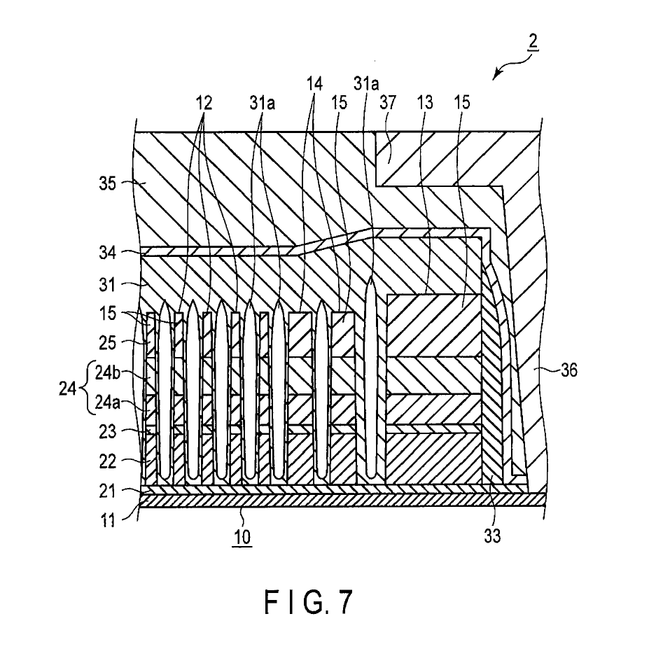

A semiconductor device and a manufacturing method of a semiconductor device according to a second embodiment will be described with reference to FIG. 7.

This embodiment employs an NAND flash memory 2. As shown in FIG. 7, the NAND flash memory 2 has two dummy gate electrodes 14 between a selection transistor 13 and a word line 12 in an end of a memory cell 10. This embodiment can suppress deformation such as bending of the word lines 12 more effectively.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a memory cell comprising a plurality of word lines arranged as an arrangement on a semiconductor substrate and apart from each other, and a selection transistor being apart from an end of said arrangement;
a dummy gate electrode having a structure larger than a width size of said word line in said arrangement direction, and arranged between the end of said arrangement and said selection transistor; and
an interlayer insulation film existed above a region including said word line, said dummy gate electrode and said selection transistor, and between said neighboring word lines, said dummy gate electrode and said selection transistor, and having a cavity between said neighboring word lines.

2. The semiconductor device according to claim 1, wherein
a width size of said dummy gate electrode is smaller than a width size of said selection transistor.

3. The semiconductor device according to claim 1, wherein
a width size of said dummy gate electrode is equal to or larger than a pitch in said arrangement of said word lines, and is equal to or smaller than ½ of a width size of said selection transistor.

4. The semiconductor device according to claim 2, wherein
a width size of said dummy gate electrode is equal to or larger than a pitch in said arrangement of said word lines, and is equal to or smaller than ½ of a width size of said selection transistor.

5. The semiconductor device according to claim 1, wherein
each of said plurality of word lines, said selection transistor and said dummy gate electrode comprises a multilayer including a first insulation film, a floating gate electrode, a second insulation film and a control electrode, and
etching processing for forming said word line or said selection transistor forms said dummy gate electrode.

6. The semiconductor device according to claim 2, wherein
each of said plurality of word lines, said selection transistor and said dummy gate electrode comprises a multilayer including a first insulation film, a floating gate electrode, a second insulation film and a control electrode, and
etching processing for forming said word line or said selection transistor forms said dummy gate electrode.

7. The semiconductor device according to claim 3, wherein
each of said plurality of word lines, said selection transistor and said dummy gate electrode comprises a multilayer including a first insulation film, a floating gate electrode, a second insulation film and a control electrode, and
etching processing for forming said word line or said selection transistor forms said dummy gate electrode.

8. The semiconductor device according to claim 4, wherein
each of said plurality of word lines, said selection transistor and said dummy gate electrode comprises a multilayer including a first insulation film, a floating gate electrode, a second insulation film and a control electrode, and
etching processing for forming said word line or said selection transistor forms said dummy gate electrode.

9. A method of manufacturing a semiconductor device comprising:
forming a multilayered gate structure comprising a first insulation film, a floating electrode layer, a second insulation film and a control electrode layer in a multilayered fashion on a semiconductor substrate;
forming a plurality of word lines as an arrangement by etching said multilayered gate structure, the word lines being arranged on said semiconductor substrate and apart from each other;
forming a selection transistor by etching said multilayered gate structure, the selection transistor being arranged apart from an end of said arrangement; and
forming a dummy gate electrode with forming said word line or said selection transistor, said dummy gate electrode having a width larger than a width of each word line in said arrangement direction, and arranged between said word line at the end of said arrangement and said selection transistor.
